(19) United States
(12) Patent Application Publication
(10) Pub. No.: US 2025/0324752 A1
(43) Pub. Date: Oct. 16, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Chih-Yang Chen, Hsinchu City (TW)

(73) Assignee: Taiwan Semiconductor Manufacturing Company, Ltd., Hsinchu (TW)

(21) Appl. No.: 18/631,525

(22) Filed: Apr. 10, 2024

(51) Int. Cl. H01L 27/092; H01L 21/822; H01L 21/8238; H01L 29/06; H01L 29/08; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 62/151; H10D 64/017; H10D 64/018; H10D 84/0167; H10D 84/017; H10D 84/038; H10D 88/01

(57) ABSTRACT

A semiconductor structure is provided. The semiconductor structure includes a bottom transistor. The bottom transistor includes a plurality of first nanostructures and a first gate structure wrapping the first nanostructures. The semiconductor structure also includes a top transistor above the bottom transistor. The top transistor includes a plurality of second nanostructures and a second gate structure wrapping the second nanostructures. The first width of one of the first nanostructures is greater than the second width of one of the second nanostructures. The semiconductor structure includes a first middle dielectric layer between the first gate structure and the second gate structure, and the first middle dielectric layer has a third width. The third width is larger than the second width.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, complementary FET (CFET) have been introduced. In a CFET structure, nMOS and pMOS devices are stacked on top of each other, so that the effective channel width of the resulting device may be further maximized. However, integration of fabrication of the CFET devices can be challenging.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2 is a layout of a semiconductor structure, in accordance with some embodiments.

FIGS. 3A-1 to 3P-1 illustrate cross-sectional representations of various stages of manufacturing the semiconductor structure shown along line X-X in FIG. 2, in accordance with some embodiments.

FIGS. 3A-2 to 3P-2 illustrate cross-sectional representations of various stages of manufacturing the semiconductor structure shown along line Y1-Y1 in FIG. 2, in accordance with some embodiments.

FIGS. 3E-3 to 3P-3 illustrate cross-sectional representations of various stages of manufacturing the semiconductor structure shown along line Y2-Y2 in FIG. 2, in accordance with some embodiments.

FIGS. 4-1 and 4-2 illustrate cross-sectional representations of various stages of manufacturing the semiconductor structure shown along line X-X and Y1-Y1 in FIG. 2, in accordance with some embodiments.

FIGS. 5-1 and 5-2 illustrate cross-sectional representations of various stages of manufacturing the semiconductor structure shown along line X-X and Y1-Y1 in FIG. 2, in accordance with some embodiments.

FIGS. 6-1 and 6-2 illustrate cross-sectional representations of various stages of manufacturing the semiconductor structure shown along line X-X and Y1-Y1 in FIG. 2, in accordance with some embodiments.

FIGS. 7-1 and 7-2 illustrate cross-sectional representations of various stages of manufacturing the semiconductor structure shown along line X-X and Y1-Y1 in FIG. 2, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a number of complementary field-effect transistor (CFET) structures, and each of the CFET structures may include a set of transistors, including a bottom transistor and a top transistor vertically stacked. The width of the channel layers of the top transistor is different than the width of the channel layers of the bottom transistor, and thus the performance of the top transistor and that of the bottom transistor can be independently adjusted. Therefore, a greater design flexibility for integrated circuits may be achieved.

In addition, the top transistor and the bottom transistor may further have different channel numbers, channel materials, channel width, and/or gate electrode materials, in accordance with some embodiments. Therefore, depending on the types of the resulting integrated circuits, the performance of integrated circuits can be improved by optimally adjusting these differences. The source/drain (S/D) structure or region(s) may refer to a source or a drain, individually or collectively dependent upon the context.

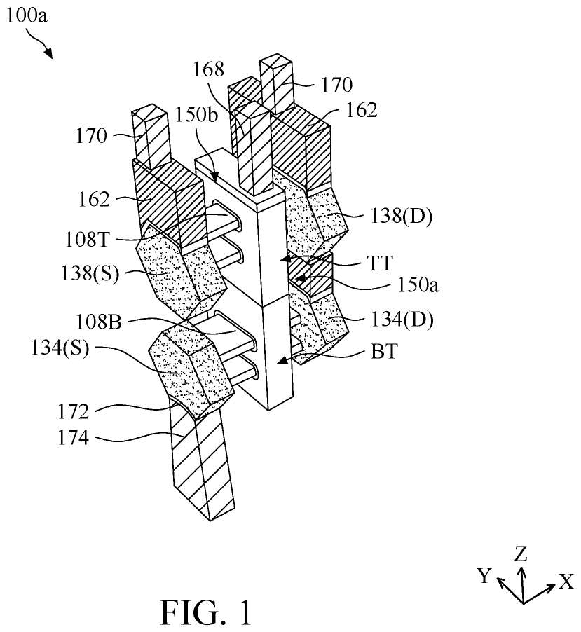

FIG. 1 is a perspective view of a semiconductor structure 100a, in accordance with some embodiments. FIG. 1 is not drawn to scale for clarity, and some features are not shown for clarity. The semiconductor structure 100a includes a fin element (not shown), an isolation structure 116 surrounding the fin element, a bottom transistor BT above the fin element, and a top transistor TT directly above the bottom transistor BT, in accordance with some embodiments. Both the top transistor TT and the bottom transistor BT are nanostructure transistors such as GAA transistors, in accordance with some embodiments.

For a better understanding of the semiconductor structure, X-Y-Z coordinate reference is provided in the figures of the present disclosure. The X-axis and the Y-axis are generally orientated along the lateral (or horizontal) directions that are parallel to the main surface of the substrate. The Y-axis is transverse (e.g., substantially perpendicular) to the X-axis. The Z-axis is generally oriented along the vertical direction that is perpendicular to the main surface of the substrate (or the X-Y plane).

In some embodiments, the bottom transistor BT is a p-channel FET, and the top transistor TT is an n-channel FET. In some other embodiments, the bottom transistor BT is an n-channel FET, and the top transistor TT is a p-channel FET. The semiconductor structure 100a may be used to form STD cells e.g., CMOS inventor, NADN, NOR, AND, OR, Flip-Flop, and/or SCAN cell regions, and/or memory cells such as SRAM.

The bottom transistor BT includes a plurality of nanostructures 108B, first S/D structure 134 (including 134(S) for the source terminal and 134(D) for the drain terminal) adjoining the nanostructures 108B, and the bottom portion of a first gate structure 150a wrapped around the nanostructures 108B, in accordance with some embodiments. The top transistor TT includes a plurality of nanostructures 108T, second S/D structure 138 (including the 138(S) for the source terminal and 138(D) for the drain terminal) adjoining the nanostructures 108T, and the top portion of the second gate structure 150b wrapped around the nanostructures 108T, in accordance with some embodiments.

The semiconductor structure 100a also includes S/D contact structure 162 landing on the S/D structure 138(S), 138(D) and 134(D), a gate via 168 landing on the second gate structure 150b, and a S/D (source/drain) via 170 landing on the S/D contact structure 162, in accordance with some embodiments.

The semiconductor structure 100 also includes a backside contact plug 174 which is formed in the fin element and abuts the backside surface of the first S/D structure 134(S). The bottom transistor BT is a first-type channel FET, and the top transistor TT is a second-type channel FET. In some embodiments where the bottom transistor BT is a p-channel FET, and the top transistor TT is an n-channel FET, the second S/D structure 138(S) of the top transistor TT is electrically connected to a VSS frontside power rail formed in a frontside metal layer (not shown), and the first S/D structure 134(S) of the bottom transistor BT is electrically connected to a VDD backside power rail formed in a backside metal layer (not shown).

The second S/D structure 138(S) and the first S/D structure 134(S) are electrically isolated from each other, in accordance with some embodiments. In some other embodiments, the first S/D structure 134(S) of the bottom transistor BT may be electrically connected to a VDD frontside power rail. In some embodiments, the source/drain features 138(D) and 134(D) are electrically connected to each other through the S/D contact structure 162.

The nanostructures 108B/108T extend between the S/D structures 134 and 138 in the X direction, in accordance with some embodiments. The nanostructures 108B and 108T function as the channels of the transistors BT and TT, in accordance with some embodiments. The X direction may also be referred to as the channel-extending direction. The current of the resulting semiconductor device (i.e., nanostructure transistor) flows in the X direction through the channels. In this disclosure, a S/D (source/drain) refers to a source and/or a drain. It is noted that in the present disclosure, a source and a drain are interchangeably used and the structures thereof are substantially the same.

The first gate structure 150a and the second gate structure 150b are formed with longitudinal axes parallel to the Y direction and extending across and/or surrounding the nanostructures 108B and 108T, in accordance with some embodiments. The Y direction may also be referred to as a gate-extending direction, in accordance with some embodiments. In some embodiments, the top portion of the second gate structure 150b for the top transistor TT is physically and electrically connected to the bottom portion of the first gate structure 150a for the bottom transistor BT. In some other embodiments, the top portion of the second gate structure 150b for the top transistor TT is physically and electrically isolated from the bottom portion of the first gate stack structure 150a for the bottom transistor BT.

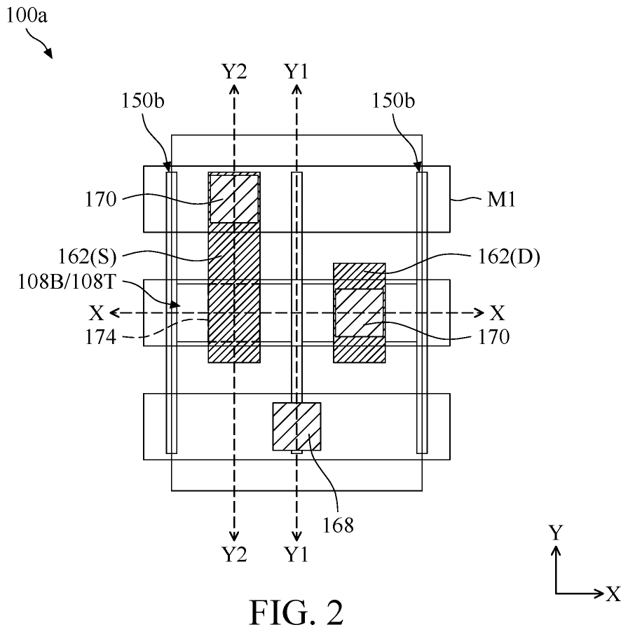

FIG. 2 illustrates the layout of the semiconductor structure 100a, in accordance with some embodiments.

The semiconductor structure 100a includes the nanostructures 108B and 108T, and first gate structures 1150a and the second gate structure 150b across the nanostructures 108B and 108T, in accordance with some embodiments. The nanostructures 108B and 108T extends in the X direction, in accordance with some embodiments. The first gate structures 150a and the second gate structures 150b extend in the Y direction and across the lower fin elements, and wrap around the nanostructures 108B and 108T, in accordance with some embodiments. The first gate structures 150a and the second gate structures 150b are combined with the nanostructures 108B and 108T to form nanostructure transistors (e.g., bottom transistor BT and top transistor TT in FIG. 1), in accordance with some embodiments.

The S/D contact structures 162 (including 162(S) for the source terminal and 162(D) for the drain terminal) are disposed on the S/D (source/drain) regions, in accordance with some embodiments. The S/D contact structures 162 are electrically connected to a frontside metal layer M1 where the S/D contact structure 162(S) serves as a Vdd/Vss node and is electrically connected to a frontside power supply line through an S/D via 170, and the S/D contact structure 162(D) serves as a non-Vdd/Vss node and is electrically connected to a signal line through the S/D via 170, in accordance with some embodiments. The second gate structure 150b is electrically connected to the frontside metal layer M1 through the gate via 168, in accordance with some embodiments.

A backside contact plug 174 is disposed on the backside of the first S/D structure 134, in accordance with some embodiments. The backside contact plug 174 serves as a Vdd/Vss node and is electrically connected to a backside power rail.

FIG. 2 further illustrates reference cross-sections that are used in later figures. Cross-section X-X is in a plane parallel to the longitudinal axis (X direction) of the nanostructures 108B and 108T, in accordance with some embodiments. Cross-section Y1-Y1 is in a plane parallel to the longitudinal axis (Y direction) of the second gate stack 150b and through the second gate stack 150b, in accordance with some embodiments. Cross-section Y2-Y2 is in a plane parallel to the longitudinal axis (Y direction) of the second gate stack 150b and through across the Vdd/Vss nodes of the source/drain region, in accordance with some embodiments.

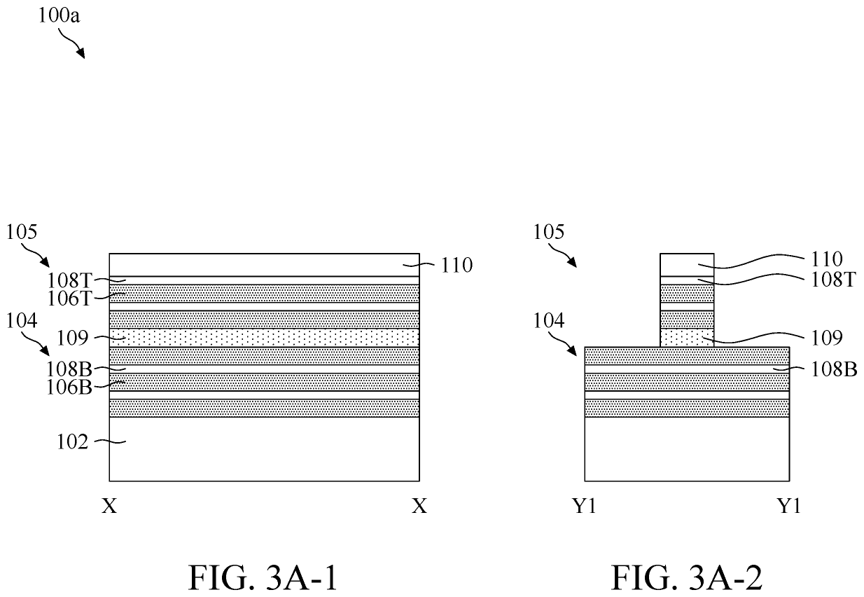

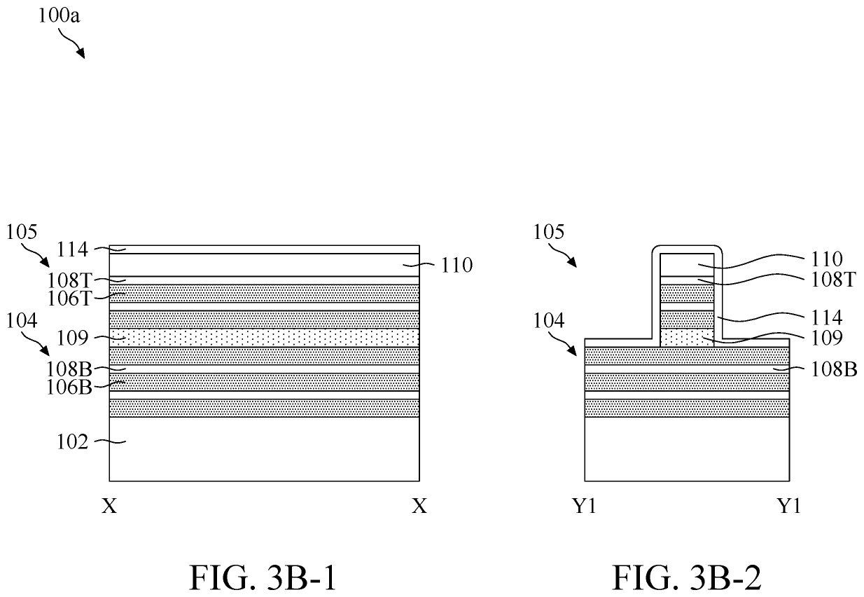

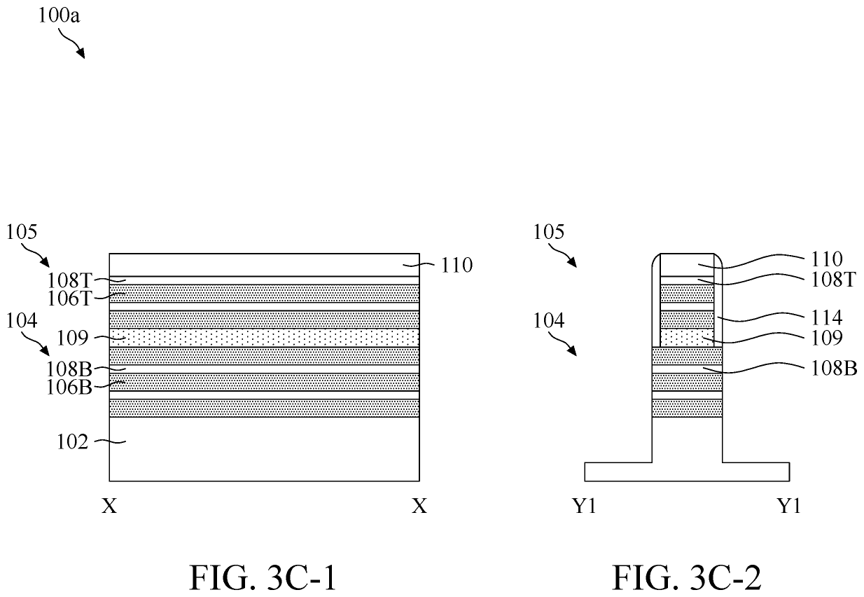

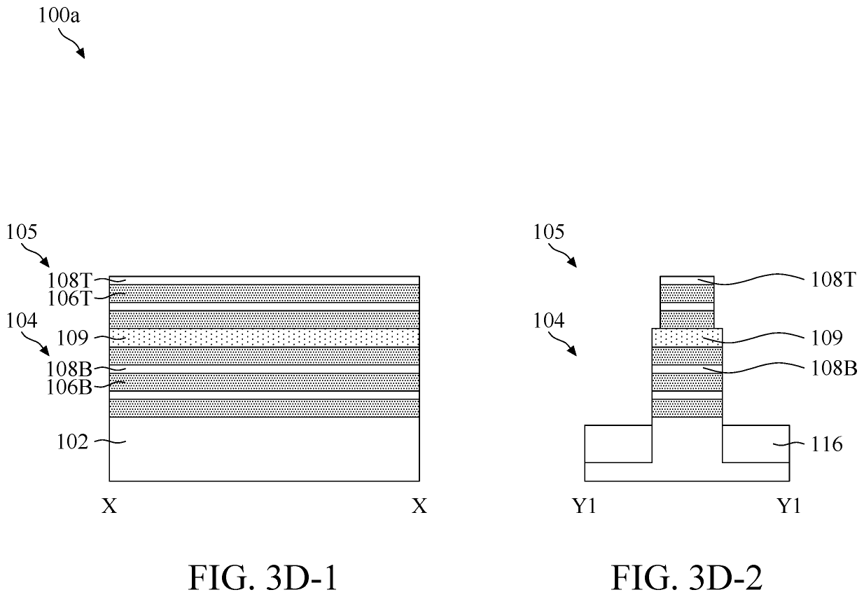

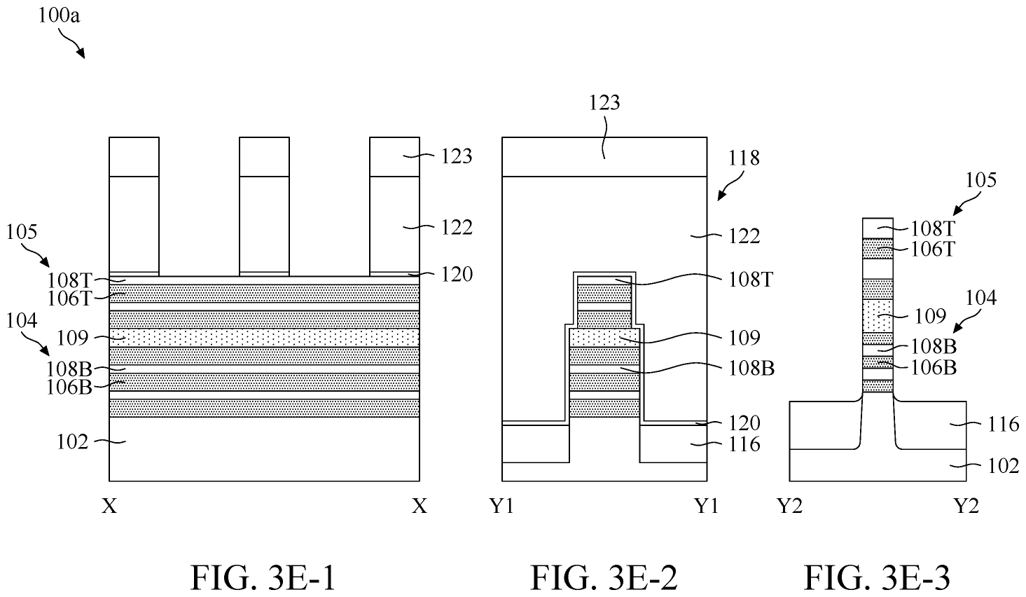

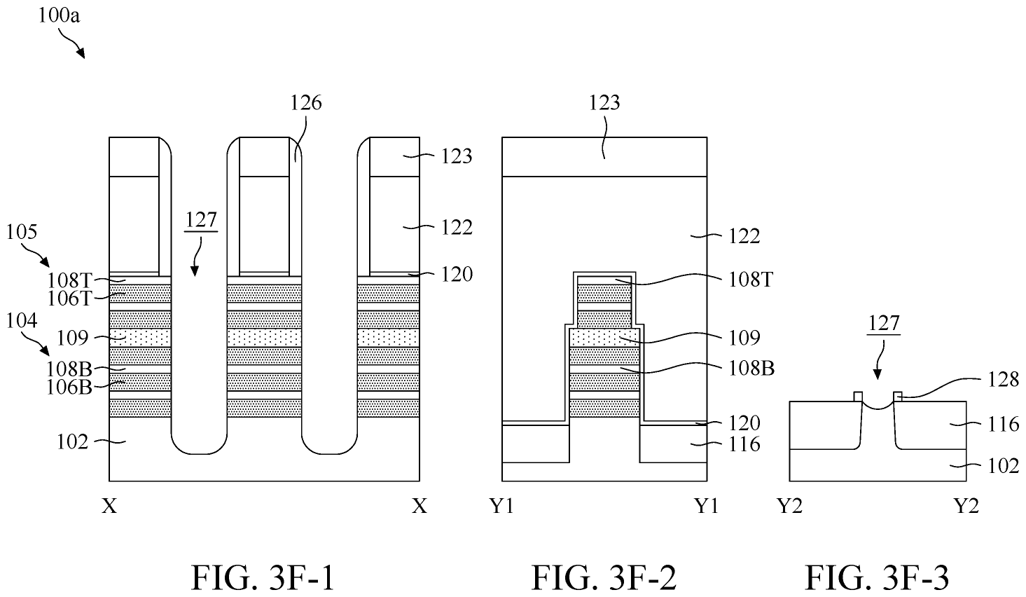

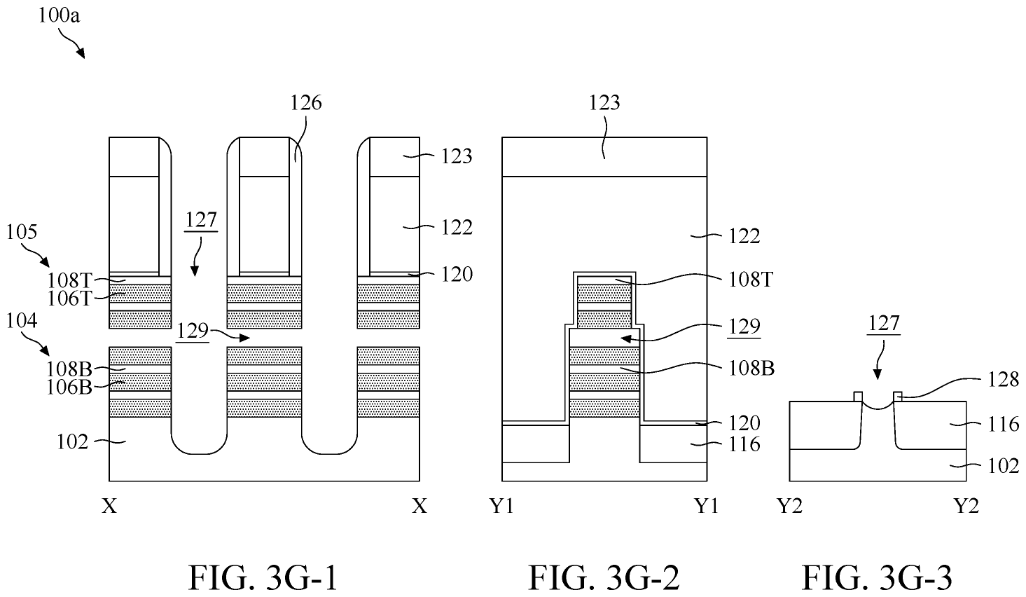

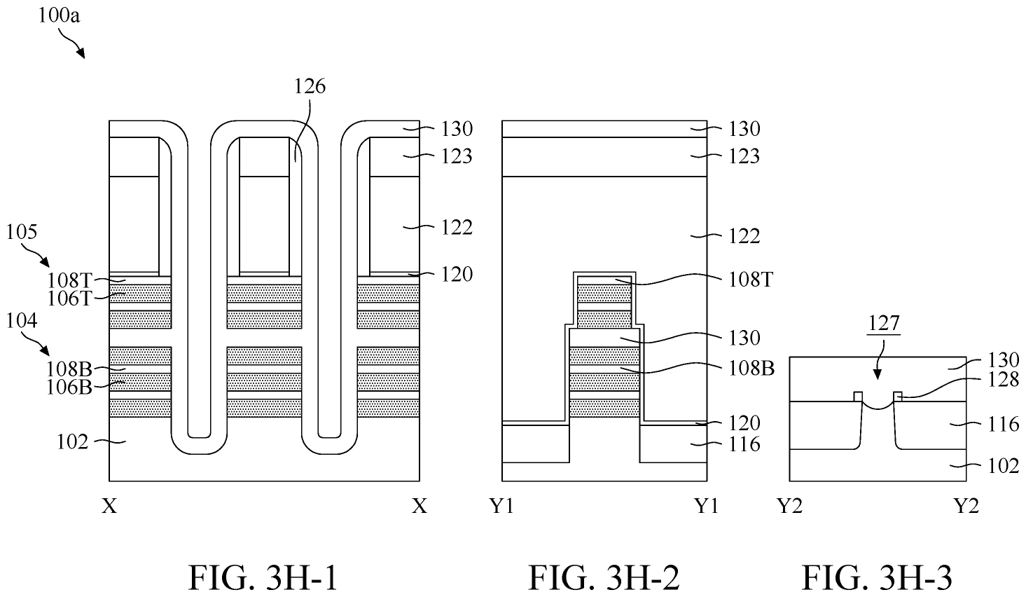

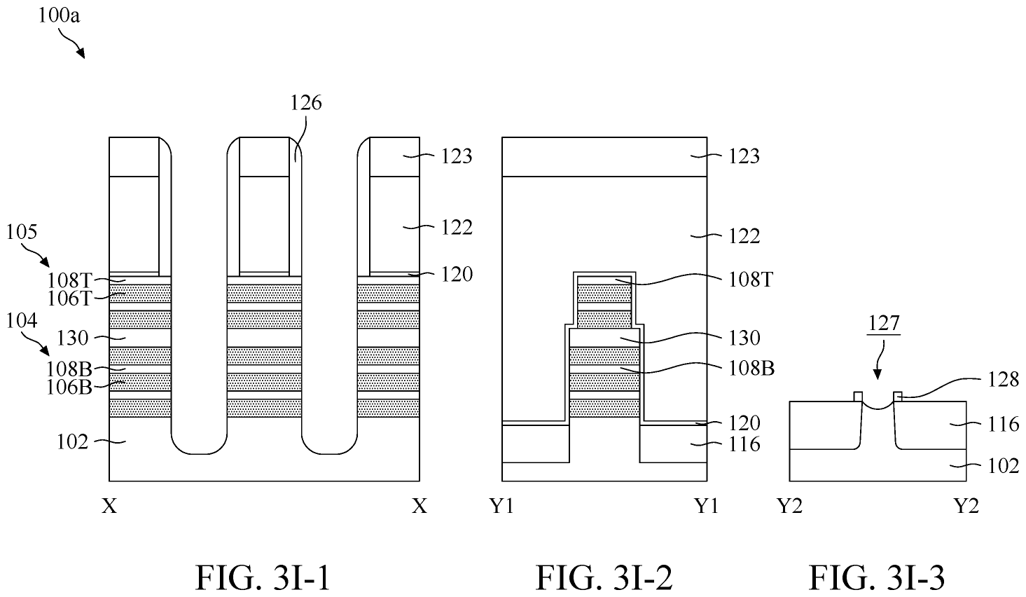

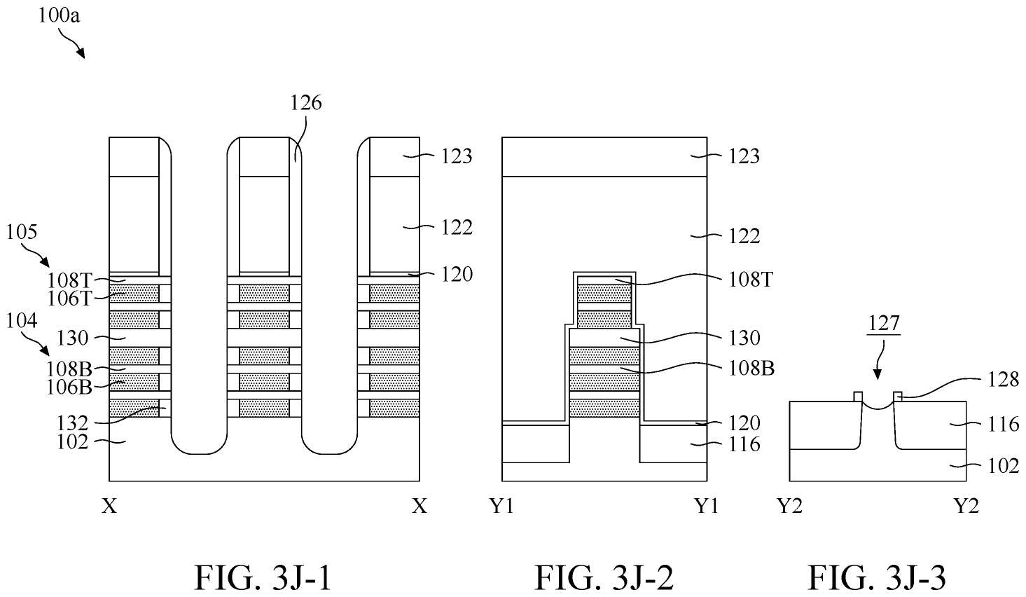

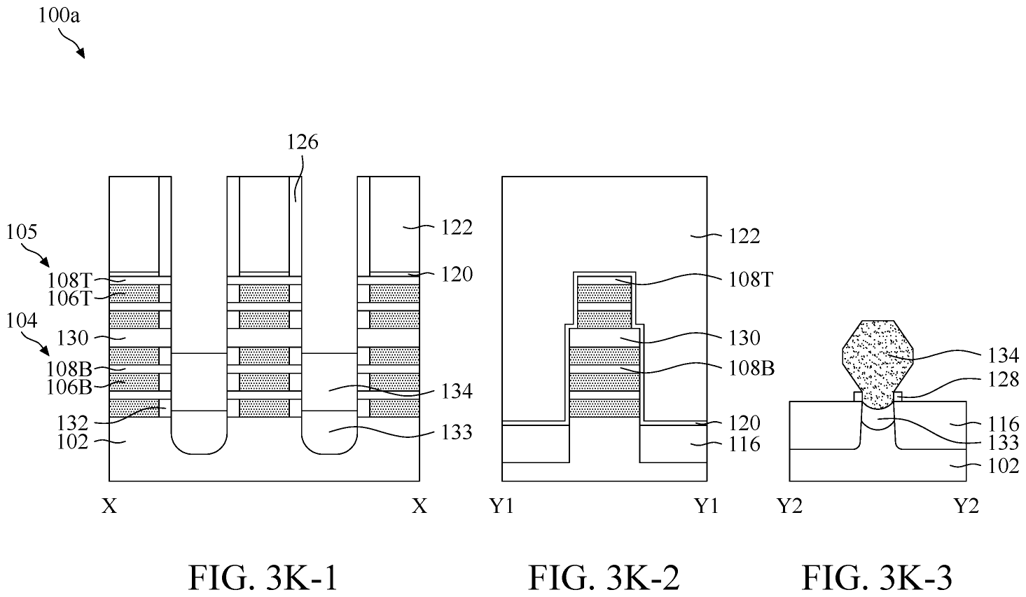

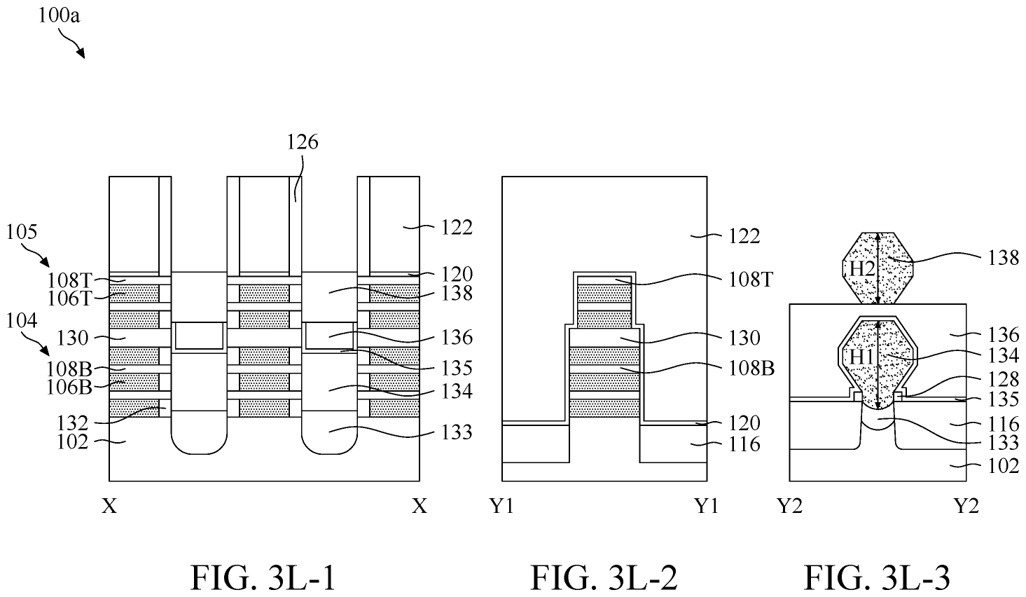

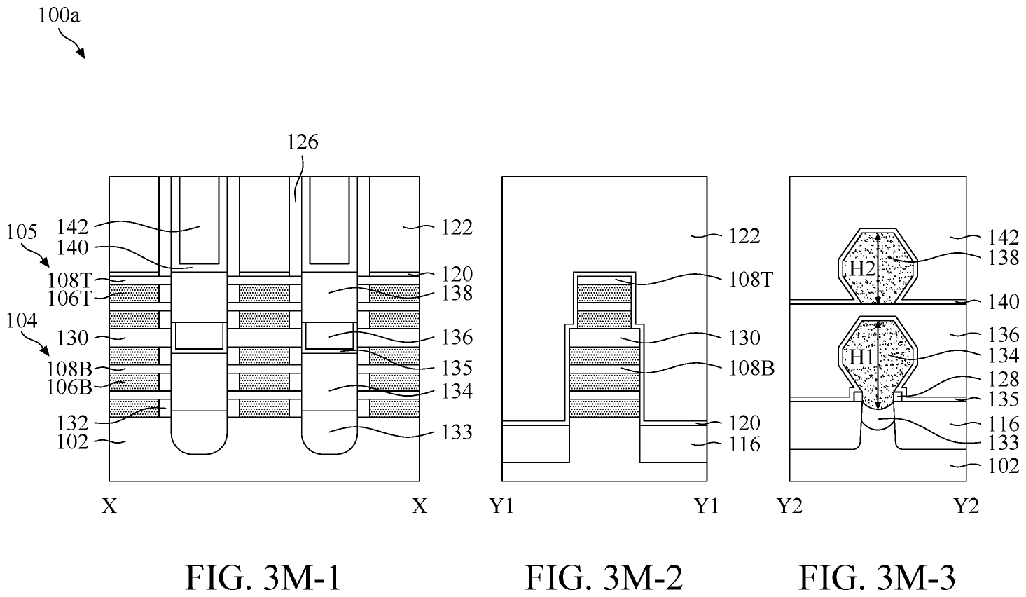

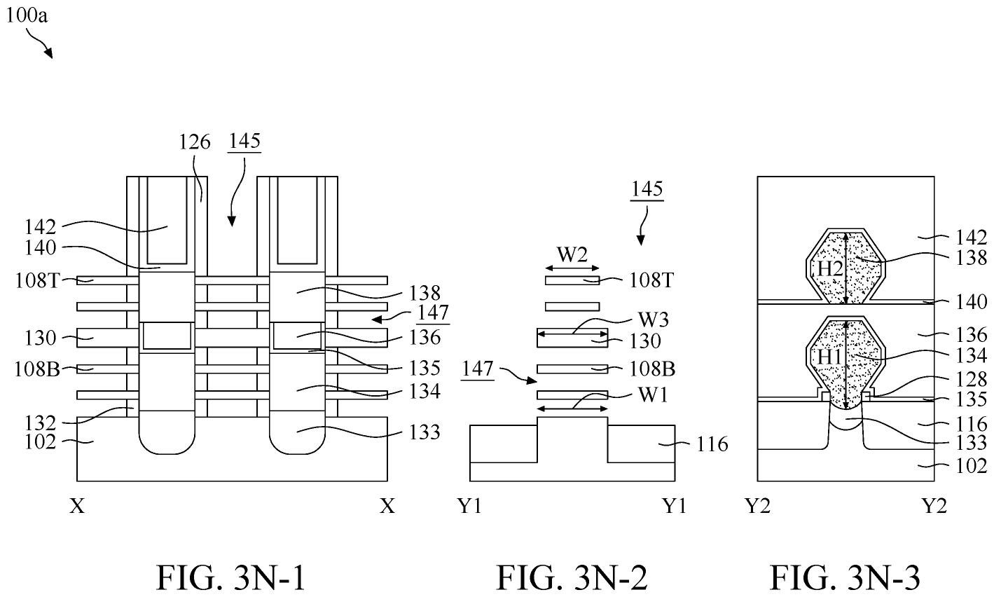

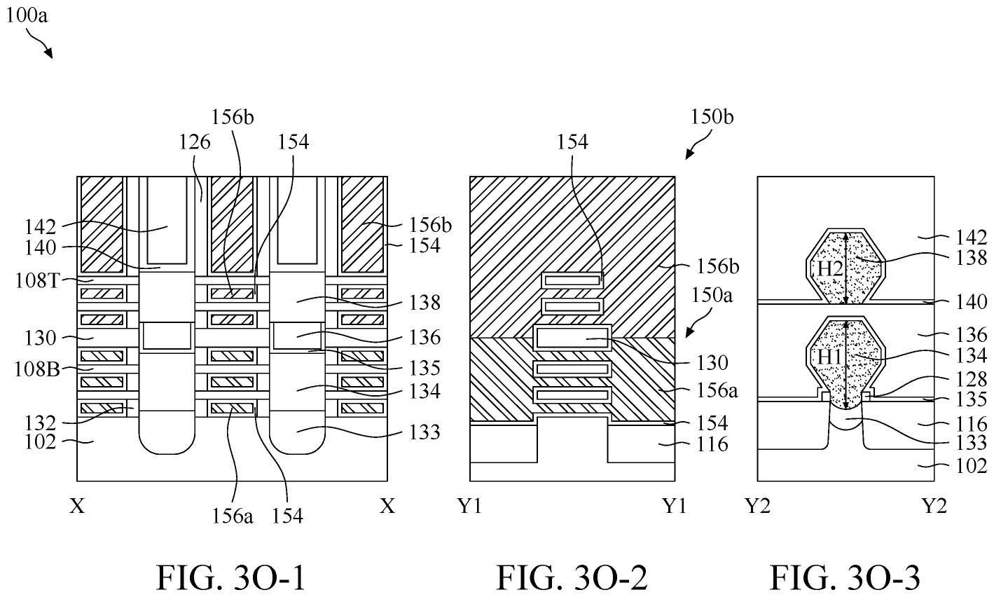

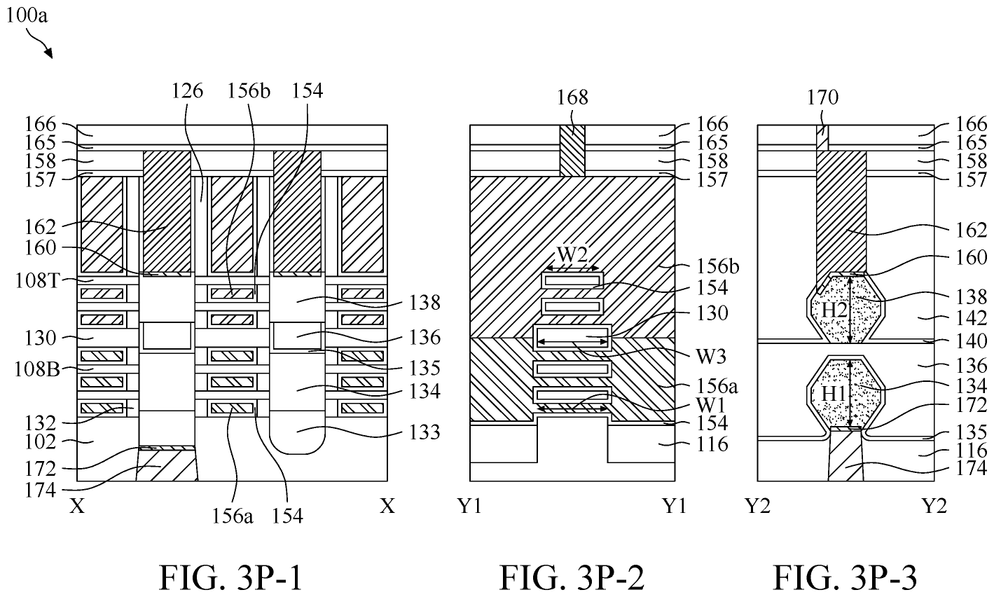

FIGS. 3A through 3P-3 are cross-sectional views illustrating the formation of the semiconductor structure 100a of FIG. 2 at various intermediate stages, in accordance with some embodiments of the disclosure. FIGS. 3A-1 to 3P-1 illustrate cross-sectional representations of various stages of manufacturing the semiconductor structure 100a shown along line X-X in FIG. 2, in accordance with some embodiments. FIGS. 3A-2 to 3P-2 illustrate cross-sectional representations of various stages of manufacturing the semiconductor structure 100a shown along line Y1-Y1 in FIG. 2, in accordance with some embodiments. FIGS. 3E-3 to 3P-3 illustrate cross-sectional representations of various stages of manufacturing the semiconductor structure 100a shown along line Y2-Y2 in FIG. 2, in accordance with some embodiments.

As shown in FIGS. 3A-1 and 3A-2, a first stack structure 104 is formed over a substrate 102, a sacrificial layer 109 is formed over the first stack structure 104 and a second stack structure 105 is formed over the sacrificial layer 109, in accordance with some embodiments. The semiconductor structure 100a is used to form CFET devices in which n-type devices and p-type devices are stacked.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

The first stack structure 104 includes the first semiconductor layers 106B and the second semiconductor layers 108B are alternatively stacked. The second stack structure 105 includes the first semiconductor layers 106T and the second semiconductor layers 108T are alternatively stacked. The sacrificial layer 109 is made of first semiconductor layers. The first semiconductor layers 106B and the second semiconductor layers 108B are made of different materials. The first semiconductor layers 106T and the second semiconductor layers 108T are made of different materials. The first semiconductor layers 106B and 106T has a different lattice constant than the second semiconductor layers 108B and 108T, in accordance with some embodiments. In some embodiments, the first semiconductor layers 106B and 106T and the second semiconductor layers 108B and 108T have different oxidation rates and/or etching selectivity.

In some embodiments, the first semiconductor material layers 106B, 106T are made of SiGe, and the second semiconductor material layers 108B, 108T are made of silicon. In some embodiments, the sacrificial layer 109 is made of SiGe. In some embodiments, the concentration of the germanium (Ge) of the sacrificial layer 109 is higher that of the first semiconductor material layers 106B, 106T. In some embodiments, the concentration of the germanium (Ge) of the sacrificial layer 109 is in a range from about 50% to about 80%. In some embodiments, the concentration of the germanium (Ge) of the first semiconductor material layers 106B, 106T is in a range from about 20% to about 30%.

The first stack structure 104 and the second stack structure 105 are formed using an epitaxial growth process, in accordance with some embodiments. The epitaxial growth process may be molecular beam epitaxy (MBE), metal organic chemical vapor deposition (MOCVD), vapor phase epitaxy (VPE), or another suitable technique.

The sacrificial layer 109 is formed between the bottom device region and the top device region, in accordance with some embodiments. The bottom device region includes the semiconductor layers 106B and 108B while the top device region includes the semiconductor layers 106T and 108T, in accordance with some embodiments.

In some embodiments, the bottom device region is used to form p-type devices (e.g., p-channel nanostructure transistors), and the top device region is used to form n-type devices (e.g., n-channel nanostructure transistors). In some other embodiments, the bottom device region is used to form n-type devices (e.g., n-channel nanostructure transistors), and the top device region is used to form p-type devices (e.g., p-channel nanostructure transistors).

The bottom device region of the first stack structure 104 is formed by depositing the first semiconductor layer 106B on the substrate 102, depositing the second semiconductor layer 108B on the first semiconductor layer 106B, and repeating the cycle of depositing the semiconductor layers 106B and 108B several times. As such, the first semiconductor layers 106B and the second semiconductor layers 108B are alternately stacked vertically, in accordance with some embodiments. The sacrificial layer 109 is then formed on the topmost layer (e.g., the topmost layer 108B) of the bottom device region, in accordance with some embodiments.

In some embodiments, each of the first semiconductor layers 106B in the bottom device region has a thickness T1 in a range from about 3 nm to about 15 nm. In some embodiments, each of the second semiconductor layers 108B in the bottom device region has a thickness T2 in a range from about 3 nm to about 15 nm.

The top device region of the second stack structure 105 is formed by depositing the second semiconductor layer 108T on the sacrificial layer 109, depositing the first semiconductor layer 106T on the first semiconductor layer 106T, and repeating the cycle of depositing the semiconductor layers 108T and 106T several times. As such, the first semiconductor layers 106T and the second semiconductor layers 108T are alternately stacked vertically, in accordance with some embodiments. It should be noted that the number of first semiconductor material layers 106B, 106T and the number of second semiconductor material layers 108B and 108T can be adjusted according to actual application.

In some other embodiments, the sacrificial layer 109 has a thickness T3 in a range from about 10 nm to about 30 nm. In some embodiments, each of the first semiconductor layers 106T in the top device region has a thickness T4 in a range from about 3 nm to about 15 nm. In some embodiments, each of the second semiconductor layers 108T in the top device region has a thickness T5 in a range from about 3 nm to about 15 nm.

Although two second semiconductor layers 108B and two second semiconductor layers 108T are shown in FIG. 3A-1, the numbers are not limited to two, and can be 1, 3 or more than 3. In some embodiments, the number of second semiconductor layers 108B is the same as the number of second semiconductor layers 108T. In some other embodiments, the number of second semiconductor layers 108B may be different than the number of second semiconductor layers 108T.

The sacrificial layer 109 will be replaced with dielectric layer (shown in FIG. 3H-1, 3H-2). The first semiconductor layers 106B and 106T and will be removed to form gaps to accommodate gate materials, in accordance with some embodiments. The second semiconductor layers 108B and 108T will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape. A gate stack (not shown) will be formed across and wrap around the nanostructures, in accordance with some embodiments.

Afterwards, a hard mask layer 110 is formed on the second stack structure 105, and a patterning process is performed on the second stack structure 105 and the sacrificial layer 109. The patterning process includes photolithography processes and etching processes. As a result, the second stack structure 105 is narrowed along the second direction (e.g. Y-axis) to form a patterned second stack structure 105.

Next, as shown in FIGS. 3B-1 and 3B-2, a spacer layer 114 is formed on the hard mask layer 110 and the patterned second stack structure 105, in accordance with some embodiments. More specifically, the spacer layer 114 is formed on the exposed top surface of the topmost first semiconductor layer 106B.

In some embodiments, the spacer layer 114 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the spacer layer 114 is formed by chemical vapor deposition (CVD), physical vapor deposition, (PVD), atomic layer deposition (ALD), or other applicable processes.

Afterwards, as shown in FIGS. 3C-1 and 3C-2, the first stack structure 104 and a portion of the substrate 102 are patterned by using the spacer layer 114 as the mask, in accordance with some embodiments. As a result, the first stack structure 104 is narrowed along the second direction (e.g. Y-axis) to form a patterned first stack structure 104. The patterning process includes photolithography processes and etching processes.

Next, as shown in FIGS. 3D-1 and 3D-2, the spacer layer 114 is removed, and the isolation material is formed on the patterned first stack structure 104 and the patterned second stack structure 105, in accordance with some embodiments.

A planarization process is performed on the isolation material to remove a portion of the isolation material. The planarization may be chemical mechanical polishing (CMP), an etching back process, or a combination thereof. Next, the hard mask layer 110 is removed, and the isolation material is then recessed by an etching process (such as dry plasma etching and/or wet chemical etching) to expose the sidewall surfaces of the patterned first stack structure 104 and the patterned second stack structure 105. As a result, an isolation structure 116 is formed. The isolation structure 116 is referred to as shallow trench isolation (STI) feature, in accordance with some embodiments.

In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

In some embodiments, the isolation structure 116 is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

Afterwards, as shown in FIGS. 3E-1, 3E-2, and 3E-3, after the isolation structure 116 is formed, dummy gate structures 118 are formed across the patterned first stack structure 104, the sacrificial layer 109 and the patterned second stack structure 105. In some embodiments, the dummy gate structures 118 extend in the second direction (e.g. Y-axis). That is, the dummy gate structures 118 have longitudinal axes parallel to the second direction (e.g. Y-axis), in accordance with some embodiments. The dummy gate structures 118 are configured as sacrificial structures and will be replaced with the final gate stacks, in accordance with some embodiments

The dummy gate structures 118 may be used to define the source/drain (S/D) regions and the channel regions of the resulting semiconductor structure 100a. In some embodiments, the dummy gate structure 118 include dummy gate dielectric layers 120 and dummy gate electrode layers 122.

In some embodiments, the formation of the dummy gate structures 118 includes globally and conformally depositing a dielectric material for the dummy gate dielectric layer 120, depositing a material for the dummy gate electrode layer 122 over the dielectric material, planarizing the material for the dummy gate electrode layer 122, and patterning the material for the dummy gate electrode layer 122 and the dielectric material into the dummy gate structures 118.

The patterning process includes forming a patterned hard mask layer 123 over the material for the dummy gate electrode layer 122, in accordance with some embodiments. The patterned hard mask layer 123 corresponds to and overlaps the channel regions of the semiconductor structure 100a, in accordance with some embodiments. The materials for the dummy gate dielectric layer 120 and the dummy gate electrode layer 122, uncovered by the patterned hard mask layer 123, are etched away until the second semiconductor layer 108T and the top surface of the isolation structure 116 are exposed, in accordance with some embodiments.

In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the dummy gate electrode layers 122 include polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

Next, as shown in FIGS. 3F-1, 3F-2 and 3F-3, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain (S/D) structures from the dummy gate structures 118, and support the dummy gate structures 118, and the fin space layers 128 may be configured to constrain a lateral growth of subsequently formed source/drain structure and support the first stack structure 104 and the second stack structure 105.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the gate spacer layers 126 and the fin spacer layers 128 are formed by a chemical vapor deposition (CVD), atomic vapor deposition (ALD), physical vapor deposition (PVD), or another suitable process.

The formation of the gate spacer layers 126 and the fin spacer layers 128 may include conformally depositing a dielectric material covering the dummy gate structures 118, the first stack structure 104, the second stack structure 105 and the isolation structure 116 over the substrate 102, and performing an anisotropic etching process, such as dry plasma etching, to remove the dielectric layer covering the top surfaces of the gate structures 118, the first stack structure 104, the second stack structure 105, and portions of the isolation structure 116.

Next, after the gate spacer layers 126 and the fin spacer layers 128 are formed, the source/drain (S/D) regions of the fin structure 104 are recessed to form source/drain (S/D) recesses 127, as shown in in accordance with some embodiments. More specifically, the first semiconductor material layers 106B and 106T and the second semiconductor material layers 108B and 108T not covered by the dummy gate structures 118 and the gate spacer layers 126 are removed, in accordance with some embodiments. In addition, some portions of the base fin structure are also recessed to form curved top surfaces, as shown in FIG. 3F-3, in accordance with some embodiments.

In some embodiments, the patterned first stack structure 104 and the patterned second stack structure 105 are recessed by performing an etching process. The etching process may be an anisotropic etching process, such as dry plasma etching, and the dummy gate structures 118, and the gate spacer layers 126 are used as etching masks during the etching process. In some embodiments, the fin spacer layers 128 are also recessed to form lowered fin spacer layers 128′.

Afterwards, as shown in FIGS. 3G-1, 3G-2 and 3G-3, the sacrificial layer 109 is removed to form a recess 129, in accordance with some embodiments. The recess 129 is connected to the S/D recess 127. In some embodiments, the sacrificial layer 109 is removed by an etching process, such as dry etching process or wet etching process.

Next, as shown in FIGS. 3H-1, 3H-2 and 3H-3, a middle dielectric layer 130 is formed in the recess 129 and in the S/D recess 127, in accordance with some embodiments.

It should be noted that the middle dielectric layer 130 and the gate spacer layer 126 are made of different materials. The middle dielectric layer 130 has a high etching selectivity with respect to the gate spacer layer 126. When the middle dielectric layer 130 is removed while the gate spacer layer 126 is not removed in the following process. Furthermore, the middle dielectric layer 130 and the inner spacer layer 132 are made of different materials. The middle dielectric layer 130 has a high etching selectivity with respect to the inner spacer layer 132. When the inner spacer layer 132 is removed, while the middle dielectric layer 130 is not removed in the following process.

It should be noted that the middle dielectric layer 130 is between the first stack structure 104 and the second stack structure 105. More specifically, the middle dielectric layer 130 is between the first semiconductor layer 106B and the first semiconductor layer 106T. The middle dielectric layer 130 is between the second semiconductor layer 108B and the second semiconductor layer 108T.

In some embodiments, the middle dielectric layer 130 is made of silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the middle dielectric layer 130 is formed by a chemical vapor deposition (CVD), atomic vapor deposition (ALD), physical vapor deposition (PVD), or another suitable process.

Afterwards, as shown in FIGS. 3I-1, 3I-2 and 3I-3, a portion of the middle dielectric layer 130 outside of the recess 129 is removed, in accordance with some embodiments. As a result, the outer sidewall surfaces of the first semiconductor layers 106B, 106T are aligned with the outer sidewall surfaces of the middle dielectric layer 130. In addition, the outer sidewall surfaces of the second semiconductor layers 108B, 108T are aligned with the outer sidewall surfaces of the middle dielectric layer 130.

In some embodiments, the portion of the middle dielectric layer 130 is removed by an etching process, such as dry etching process or wet etching process.

Next, as shown in FIGS. 3J-1, 3J-2 and 3J-3, after the middle dielectric layer 130 are formed, the first semiconductor layers 106B, 106T exposed by the S/D (source/drain) recesses 127 are laterally recessed to form notches (not shown), and inner spacer layers 132 are formed in the notches between the second semiconductor layers 108B, 108T, in accordance with some embodiments. The inner spacer layers 132 are configured to separate the source/drain (S/D) structures and the gate structures formed in subsequent manufacturing processes in accordance with some embodiments. The sidewall surface of the inner spacer layer 132 is aligned with a sidewall surface of the first middle dielectric layer 130.

In some embodiments, an etching process is performed on the semiconductor structure 100a to laterally recess the first semiconductor material layers 106B, 106T from the S/D recesses 127. In some embodiments, during the etching process, the first semiconductor layers 106B and 106T have a greater etching rate (or etching amount) than the second semiconductor layers 108B and 108T, thereby forming notches between adjacent second semiconductor layers 108B and 108T. In some embodiments, the etching process is an isotropic etching such as dry chemical etching, remote plasma etching, wet chemical etching, another suitable technique, and/or a combination thereof.

It should be noted the middle dielectric layer 130 and the inner spacer layer 132 are made of different materials. The middle dielectric layer 130 has a high etching selectivity with respect to the inner spacer layer 132. When the inner spacer layer 132 is removed, while the middle dielectric layer 130 is not removed in the following process.

In some embodiments, the inner spacer layers 132 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layers 132 are formed by a deposition process, such as chemical vapor deposition (CVD) process, atomic layer deposition (ALD) process, another applicable process, or a combination thereof.

Afterwards, as shown in FIGS. 3K-1, 3K-2 and 3K-3, a bottom layer 133 is formed in the S/D recess 127, in accordance with some embodiments. In some embodiments, the bottom layer 133 include un-doped Si, un-doped SiGe or a combination thereof. In some embodiments, the bottom layer 133 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

Next, a first S/D structure 134 is formed on the bottom layer 133, in accordance with some embodiments. The first S/D structure 134 may include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), or a combination thereof. The first S/D structure 134 may dope with one or more dopants. In some embodiments, the first S/D structure 134 is silicon (Si) doped with phosphorus (P), arsenic (As), antimony (Sb), or another applicable dopant. Alternatively, the first S/D structure 134 is silicon germanium (SiGe) doped with boron (B) or another applicable dopant.

In some embodiments, the first S/D structure 134 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

In some embodiments, when an N-type FET (NFET) device is desired, the first S/D structure 134 includes an epitaxially growing silicon (epi Si). Alternatively, when a P-type FET (PFET) device is desired, the first S/D structure 134 includes an epitaxially growing silicon germanium (SiGe).

Next, as shown in FIGS. 3L-1, 3L-2 and 3L-3, a contact etching stop layer 135 is formed over the first S/D structure 134, in accordance with some embodiments. In some embodiments, the top surface of the contact etching stop layer 135 is higher than the top surface of the middle dielectric layer 130.

In some embodiments, the contact etching stop layer 135 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 135 is globally and conformally deposited over the semiconductor structure 100a using CVD (such as LPCVD, PECVD, HDP-CVD, or HARP), ALD, another suitable method, or a combination thereof.

A spacer dielectric layer 136 is formed over the contact etching stop layer 135, as shown in FIGS. 3L-1, 3L-2 and 3L-3, in accordance with some embodiments. The first spacer dielectric layer 136 overfills the space between dummy gate structures 118.

In some embodiments, the spacer dielectric layer 136 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the spacer dielectric layer 136 and the contact etching stop layer 135 are made of different materials and have a great difference in etching selectivity. In some embodiments, the dielectric material for the spacer dielectric layer 136 is deposited using such as CVD (such as HDP-CVD, PECVD, HARP or FCVD), another suitable technique, or a combination thereof. The dielectric materials for the contact etching stop layer 135 and the spacer dielectric layer 136 are removed using such as CMP, and then etched-back until the side surfaces of the inner spacer layers 132 are exposed, in accordance with some embodiments.

Afterwards, a second S/D structure 138 is formed on the spacer dielectric layer 136, in accordance with some embodiments. As a result, the spacer dielectric layer 136 is between the first S/D structure 134 and the second S/D structure 138.

The second S/D structure 138 may include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), or a combination thereof. The second S/D structure 138 may dope with one or more dopants. In some embodiments, the second S/D structure 138 is silicon (Si) doped with phosphorus (P), arsenic (As), antimony (Sb), or another applicable dopant. Alternatively, the second S/D structure 138 is silicon germanium (SiGe) doped with boron (B) or another applicable dopant.

In some embodiments, the second S/D structure 138 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

In some embodiments, when an N-type FET (NFET) device is desired, the second S/D structure 138 includes an epitaxially growing silicon (epi Si). Alternatively, when a P-type FET (PFET) device is desired, the second S/D structure 138 includes an epitaxially growing silicon germanium (SiGe).

The first S/D structure 134 has a first height H1, and the second S/D structure 138 has a second height H2. In some embodiments, the first height H1 is greater than the second height H2.

Next, as shown in FIGS. 3M-1, 3M-2 and 3M-3, a contact etching stop layer 140 is formed over the second S/D structure 138, and an interlayer dielectric layer 142 is formed on the contact etching stop layer 140, in accordance with some embodiments.

In some embodiments, the contact etching stop layer 140 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 140 is globally and conformally deposited over the semiconductor structure 100a using CVD (such as LPCVD, PECVD, HDP-CVD, or HARP), ALD, another suitable method, or a combination thereof.

In some embodiments, the interlayer dielectric layer 142 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the interlayer dielectric layer 142 is formed by a deposition process, such as chemical vapor deposition (CVD) process, atomic layer deposition (ALD) process, another applicable process, or a combination thereof.

Next, a portion of the interlayer dielectric layer 142 is removed to expose the top surface of dummy gate electrode layer 122 of the dummy gate structure 118. In some embodiments, the portion of the ILD layer 142 is removed by a planarizing process, a chemical mechanical polishing (CMP) process.

Next, as shown in FIGS. 3N-1, 3N-2 and 3N-3, the dummy gate electrode layer 122 and the first dummy gate dielectric layer 120 are removed to form a trench 145, in accordance with some embodiments. Next, the first semiconductor layer 106B and 106T are removed to form a number of gaps 147. As a result, the nanostructures 108B and 108T (or channel layers 108B and 108T) with the second semiconductor material layers 108 are obtained. The number of nanostructures 108B and 108T (or channel layers 108B and 108T) may be adjusted according to actual application. In addition, the middle dielectric layer 130 is exposed by the trench 145 and the gaps 147.

As shown in FIG. 3N-2, the second semiconductor layer 108B of the first stack structure 104 of the bottom transistor BT has a first width W1 along the second direction (e.g. Y-axis), the second semiconductor layer 108T of the second stack structure 105 of the of the top transistor TT has a second width W2 along the second direction (e.g. Y-axis). The middle dielectric layer 130 has a third width W3 along the second direction (e.g. Y-axis). In some embodiments, the first width W1 of the second semiconductor layer 108B is greater than the second width W2 of the second semiconductor layer 108T. In some embodiments, the third width W3 of the middle dielectric layer 130 is greater than the second width W2 of the second semiconductor layer 108T. In some embodiments, the third width W3 of the middle dielectric layer 130 is substantially equal to the first width W1 of the second semiconductor layer 108B.

The exposed second semiconductor layers 108B and 108T form nanostructures, in accordance with some embodiments. In some embodiments, a corner-rounding process may be performed on the nanostructures 108B and 108T. The nanostructures 108B and 108T are vertically stacked and spaced apart from one other, in accordance with some embodiments. The nanostructures 108B function as channels of the bottom devices of the CFET, and the nanostructures 108T function as channels of the top devices of the CFET, in accordance with some embodiments.

For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

Afterwards, as shown in FIGS. 3O-1, 3O-2 and 3O-3, after the nanostructures 108′ are formed, a first gate structure 150a and a second gate structure 150b are formed to surround the nanostructures 108′ and over the isolation structure 116, in accordance with some embodiments.

The first gate structure 150a is a first type gate structure, and the second gate structure 150b is a second type gate structure. In some embodiments, the first gate structure 150a is an N-type gate structure, and the second gate structure 150b is a P-type gate structure. In some embodiments, the first gate structure 150a is a P-type gate structure, and the second gate structure 150b is an N-type gate structure. The first gate structure 150a and the second gate structure 150b extend in the second direction (e.g. Y-axis). The first gate structure 150a and the second gate structure 150b have longitudinal axes parallel to the Y direction, in accordance with some embodiments.

The bottom portion of the first gate structure 150a that are wrapped around the bottom nanostructures 108B combine with the neighboring first S/D structure 134 to form bottom transistors BT, e.g., p-channel nanostructure transistors. The top portion of the second gate structure 150b that are wrapped around the top nanostructures 108T combine with the neighboring second S/D structure 138 to form top transistors TT, e.g., n-channel nanostructure transistors.

In some embodiments, the n-channel top transistors TT are directly stacked above the p-channel bottom transistors BT thereby constructing CFET. In some embodiments, the p-channel top transistors TT are directly stacked above the n-channel bottom transistors BT thereby constructing CFET.

In some embodiments, the first gate structure 150a includes an interfacial layer (not shown), a gate dielectric layer 154, and a first gate electrode layer 156a. In some embodiments, the second gate structure 150b includes an interfacial layer (not shown), a gate dielectric layer 154, and a second gate electrode layer 156b. After the interfacial layers, the gate dielectric layers 154, the first gate electrode layer 156a and the second gate electrode layer 156b are formed, a planarization process such as CMP or an etch-back process may be performed until the interlayer dielectric layer 142 is exposed.

In some embodiments, the interfacial layers are oxide layers formed around the nanostructures 108B and 108T. In some embodiments, the interfacial layers are formed by performing a thermal process.

In some embodiments, the gate dielectric layers 154 are formed over the interfacial layers, so that the nanostructures 108′ are surrounded (e.g. wrapped) by the gate dielectric layers 154. In addition, the gate dielectric layers 154 also cover the sidewalls of the gate spacers 126 and the inner spacers 132 in accordance with some embodiments. In some embodiments, the gate dielectric layers 154 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate dielectric layers 154 are formed using chemical vapor deposition (CVD), atomic layer deposition (ALD), another applicable method, or a combination thereof.

In some embodiments, the first gate electrode layer 156a and the second gate electrode layer 156b are formed on the gate dielectric layer 154. In some other embodiments, first gate electrode layer 156a is formed firstly, and the second gate electrode layer 156b is formed later.

In some embodiments, the first gate electrode layer 156a and the second gate electrode layer 156b are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the first gate electrode layer 156a and the second gate electrode layer 156b are formed by using chemical vapor deposition (CVD), atomic layer deposition (ALD), electroplating, another applicable method, or a combination thereof. Other conductive layers, such as work function metal layers, may also be formed in first gate electrode layer 156a and the second gate electrode layer 156b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Afterwards, as shown in FIGS. 3P-1, 3P-2 and 3P-3, an etching stop layer 157 is formed on the second gate electrode layer 156b of the second gate structure 150b, a dielectric layer 158 is formed on the etching stop layer 157, and a silicide layer 160 and an S/D contact structure 162 are formed over the S/D structures 138, in accordance with some embodiments.

In some embodiments, the contact openings may be formed through the dielectric layer 158, the etching stop layer 157, the interlayer dielectric layer 142 and etching stop layer 140 to expose the top surfaces of the second S/D structures 138, and then the silicide layers 160 and the S/D contact structure 162 may be formed in the contact openings. The contact openings may be formed using a photolithography process and an etching process. In addition, some portions of the second S/D structures 138 exposed by the contact openings may also be etched during the etching process.

In some embodiments, the etching stop layer 157 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the etching stop layer 157 is globally and conformally deposited over the semiconductor structure 100a using CVD (such as LPCVD, PECVD, HDP-CVD, or HARP), ALD, another suitable method, or a combination thereof.

In some embodiments, the dielectric layer 158 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the dielectric layer 158 is formed by a deposition process, such as chemical vapor deposition (CVD) process, atomic layer deposition (ALD) process, another applicable process, or a combination thereof.

The silicide layers 160 may be formed by forming a metal layer over the top surfaces of the second S/D structures 138 and annealing the metal layer so the metal layer reacts with the second S/D structures 138 to form the silicide layers 160. The unreacted metal layer may be removed after the silicide layers 154 are formed.

The S/D contact structures 162 may include a barrier layer and a conductive layer. In some other embodiments, the S/D contact structures 162 do not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

Next, an etching stop layer 165 is formed on the dielectric layer 158, and a dielectric layer 166 is formed on the etching stop layer 165, the S/D via 170 is formed over the S/D contact 162, and the gate via 168 is formed on the second gate electrode layer 156b of the second gate structure 150b, in accordance with some embodiments. The S/D via 170 is electrically connected to the second S/D structure 138 by the S/D contact structure 162.

In some embodiments, the openings may be formed through the dielectric layer 166, the etching stop layer 165, the dielectric layer 158, the etching stop layer 157 to expose the top surfaces of the second gate electrode layer 156b of the second gate structure 150b, and then the gate via 168 may be formed in the openings. The contact openings may be formed using a photolithography process and an etching process.

In some embodiments, the openings may be formed through the dielectric layer 166, the etching stop layer 165 to expose the top surfaces of the S/D contact structure 162, and then the S/D via 170 may be formed in the openings.

In some embodiments, the etching stop layer 165 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the etching stop layer 165 is globally and conformally deposited over the semiconductor structure 100a using CVD (such as LPCVD, PECVD, HDP-CVD, or HARP), ALD, another suitable method, or a combination thereof.

In some embodiments, the dielectric layer 166 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the dielectric layer 166 is formed by a deposition process, such as chemical vapor deposition (CVD) process, atomic layer deposition (ALD) process, another applicable process, or a combination thereof.

In some embodiments, the gate via 168 is made of conductive material, such as tungsten (W), ruthenium (Ru), molybdenum (Mo), or the like. In some embodiments, the gate via 168 is formed by performing a deposition process, such as chemical vapor deposition (CVD), physical vapor deposition, (PVD), atomic layer deposition (ALD), or other applicable processes.

In some embodiments, the S/D via 170 is made of conductive material, such as tungsten (W), ruthenium (Ru), molybdenum (Mo), or the like. In some embodiments, the S/D via 170 is formed by performing a deposition process, such as chemical vapor deposition (CVD), physical vapor deposition, (PVD), atomic layer deposition (ALD), or other applicable processes

The semiconductor structure 100a may undergo further frontside MEOL and/or BEOL processes to form various interconnection conductive features (not shown) over the semiconductor structure 100a, such as frontside metal layers and vias between neighboring two metal layers.

A silicide layer 172 and a backside contact plug 174 are formed to abut the backside surface of first S/D structure 134 for the source terminal, as shown in FIGS. 3P-1 and 3P-3, in accordance with some embodiments. In some embodiments where the bottom transistor BT is a p-channel FET and the top transistor TT is an n-channel FET, the source terminal of the bottom transistor BT is electrically connected to a VDD power rail through the backside contact plug 174, and the source terminal of the top transistor TT is electrically connected to a VSS power rail through S/D contact structure 162 and the S/D via 170.

The formations of the silicide layer 172 and the backside contact plug 174 include flipping the semiconductor structure 100a upside down, planarizing the backside of the semiconductor structure 100a using such as CMP to expose the isolation structure 116, patterning the lower portion of the stack structure 104 using photolithography and etching processes to form an opening (where the backside contact plug 174 is to be formed) exposing the first S/D structure 134. In some embodiments, the portion of the first S/D structure 134 may be also removed.

In some embodiments, the silicide layer 172 is made of WSi, NiSi, TiSi and/or CoSi. Afterward, one or more conductive materials (e.g., Ta, TaN, Ti, TiN, CoW, Co, Ni, W, Cu, Rh, Ir, Pt, Al, Ru, Mo, another suitable metal material, or a combination thereof) are deposited to overfill the opening to form the backside contact plug 174, in accordance with some embodiments. The excess conductive material outside the opening is removed, for example, using CMP and/or an etching process.

The semiconductor structure 100a may undergo further backside BEOL processes to form various interconnection conductive features (not shown) over backside of the semiconductor structure 100a, such as backside metal layers, vias between neighboring two metal layers, passivation layers, bump pads, etc.

It should be noted that, as shown in FIG. 3P-1, the outer sidewall surface of the inner spacer layer 132 is aligned with the outer sidewall surface of the middle dielectric layer 130. The outer sidewall surface of the middle dielectric layer 130 is aligned with the outer sidewall surface of the gate spacer layer 126. The outer sidewall surface of the middle dielectric layer 130 extends beyond the inner sidewall surface of the gate spacer layer 126, and the inner sidewall surface of the gate spacer layer 126 is in direct contact with the second gate structure 150b. The outer sidewall surface of the middle dielectric layer 130 extends beyond the interface between the first gate structure 150a and the inner spacer layer 132. The outer sidewall surface of the middle dielectric layer 130 also extends beyond the interface between the second gate structure 150b and the inner spacer layer 132.

In accordance with the embodiments of the present disclosure, each of the CFET devices of the semiconductor structure 100a includes a bottom transistor BT and a top transistor TT directly above the bottom transistor BT. As shown in FIG. 3P-2, the nanostructures 108B of the bottom transistor BT has the first width W1 along the second direction (e.g. Y-axis), the nanostructures 108T of the top transistor TT has the second width W2 along the second direction (e.g. Y-axis). The middle dielectric layer 130 has the third width W3 along the second direction (e.g. Y-axis). In some embodiments, the first width W1 is greater than the second width W2. In some embodiments, the third width W3 is greater than the second width W2. In some embodiments, the third width W3 is substantially equal to the first width W1.

The large effective width (W_{eff}) of channel layer (e.g. nanostructures 108B) can provide high speed and high driving current of the semiconductor structure 100a. However, the larger effective width of the channel layer consumes more power. For high speed performance consideration, larger effective width (W_{eff}) is formed by having more nanostructures. For power efficiency, a smaller effective width (W_{eff}) (e.g. nanostructures 108T) is formed by having fewer nanostructures. Thus, the performance of the top transistor TT and that of the bottom transistor BT can be independently adjusted.

Due to the independent adjustment of the performance of the n-channel nanostructure transistor (e.g., the top transistor TT) and that of the p-channel nanostructure transistor (e.g., the bottom transistor BT), a greater design flexibility for integrated circuits may be achieved. Therefore, depending on the types of the integrated circuits, the overall performance of integrated circuits can be improved by optimally adjusting the width difference between the nanostructures 108T and the nanostructures 108B.

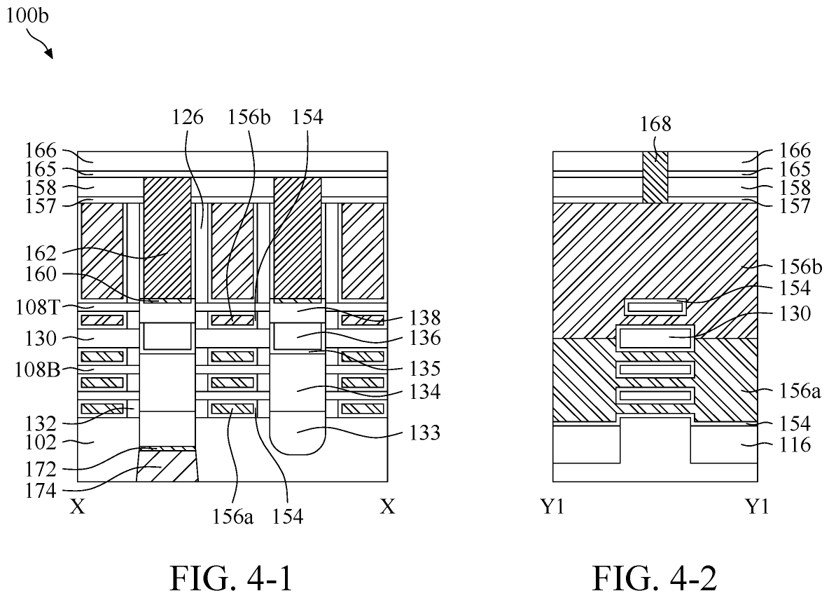

FIGS. 4-1 and 4-2 illustrate cross-sectional representations of various stages of manufacturing the semiconductor structure 100b shown along line X-X and Y1-Y1 in FIG. 2, in accordance with some embodiments. The semiconductor structure 100b of FIGS. 4-1 and 4-2 include elements that are similar to, or the same as, elements of the semiconductor structure 100a of FIG. 3A-1 to 3P-3.

The difference between FIGS. 4-1, 4-2 and 3P-1, 3P-2 is that the number of nanostructures 108T of the top transistor TT is one less than or more than one less than the number of nanostructures 108B of the bottom transistor BT. In other words, the number of nanostructures 108T may be different than the number of nanostructures 108B.

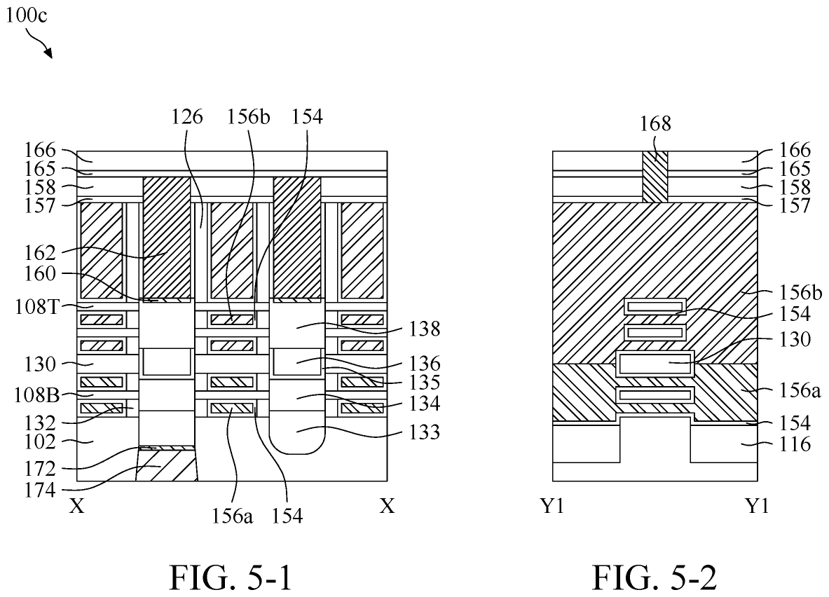

FIGS. 5-1 and 5-2 illustrate cross-sectional representations of various stages of manufacturing the semiconductor structure 100c shown along line X-X and Y1-Y1 in FIG. 2, in accordance with some embodiments. The semiconductor structure 100c of FIGS. 5-1 and 5-2 include elements that are similar to, or the same as, elements of the semiconductor structure 100a of FIG. 3A-1 to 3P-3.

The difference between FIGS. 5-1, 5-2 and 3P-1, 3P-2 is that the number of nanostructures 108B of the bottom transistor BT is one less than or more than one less than the number of nanostructures 108T of the top transistor TT. In other words, the number of nanostructures 108T may be different than the number of nanostructures 108B.

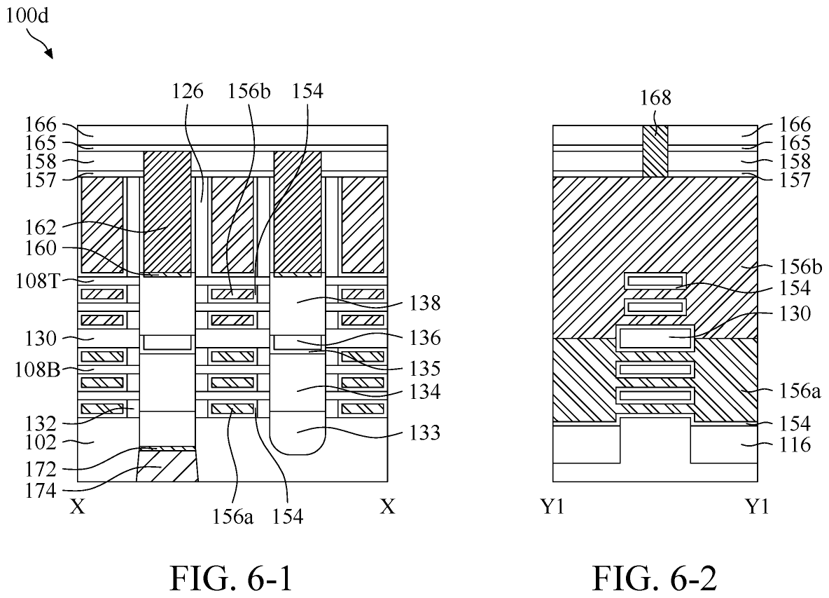

FIGS. 6-1 and 6-2 illustrate cross-sectional representations of various stages of manufacturing the semiconductor structure 100d shown along line X-X and Y1-Y1 in FIG. 2, in accordance with some embodiments. The semiconductor structure 100c of FIGS. 6-1 and 6-2 include elements that are similar to, or the same as, elements of the semiconductor structure 100a of FIG. 3A-1 to 3P-3.

The difference between FIGS. 6-1, 6-2 and 3P-1, 3P-2 is that the top surface of the etching stop layer 135 and the top surface of the spacer dielectric layer 136 are lower than the top surface of the middle dielectric layer 130.

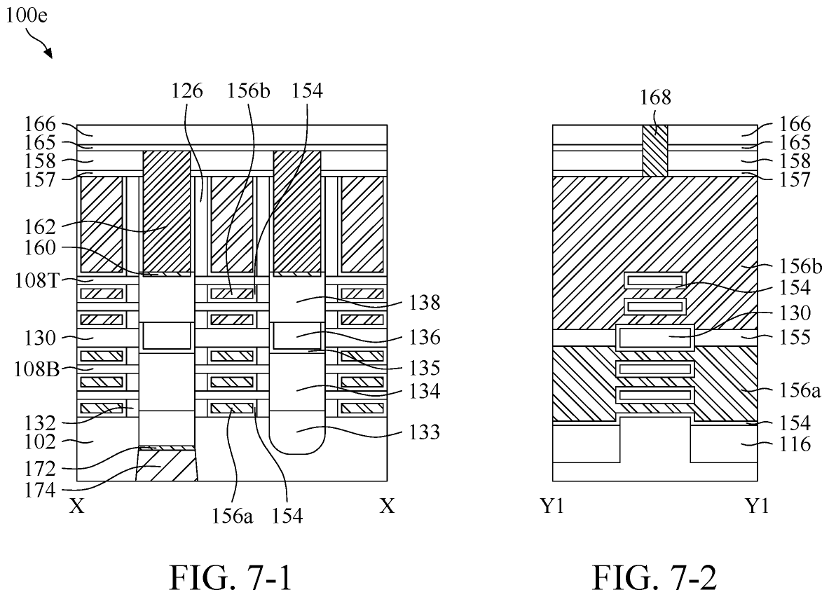

FIGS. 7-1 and 7-2 illustrate cross-sectional representations of various stages of manufacturing the semiconductor structure 100e shown along line X-X and Y1-Y1 in FIG. 2, in accordance with some embodiments. The semiconductor structure 100e of FIGS. 7-1 and 7-2 include elements that are similar to, or the same as, elements of the semiconductor structure 100a of FIG. 3A-1 to 3P-3.

The difference between FIGS. 7-1, 7-2 and 3P-1, 3P-2 is that another middle dielectric layer 155 between the first stack structure 104 and the second stack structure 105. More specifically, the middle dielectric layer 155 is between the bottom transistor

BT and the top transistor TT. The middle dielectric layer 155 is between the first gate electrode layer 156a of the second gate structure 150a and the second gate electrode layer 156b of the second gate structure 150b. The middle dielectric layer 155 is in direct contact with the middle dielectric layer 130.

In some embodiments, the middle dielectric layer 155 is made of silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the middle dielectric layer 155 is formed by a chemical vapor deposition (CVD), atomic vapor deposition (ALD), physical vapor deposition (PVD), or another suitable process.

In accordance with some embodiments of the present disclosure, the nanostructures 108T of the top transistor TT have a different width than the nanostructures 108B of the bottom transistor BT, and thus the performance of the top transistor TT and that of the bottom transistor BT can be independently adjusted. Therefore, a greater design flexibility for integrated circuits may be achieved.

As described above, the semiconductor structure includes CFET device, and each of the CFET devices includes a bottom transistor BT and top transistor TT. The width W2 of the nanostructure 108T of the top transistor TT is different than the width W1 of the nanostructure 108B of the bottom transistor BT, and thus the performance of the top transistor TT and that of the bottom transistor BT can be independently adjusted. Therefore, a greater design flexibility for integrated circuits may be achieved.

In addition, the number of nanostructures 108T may be different than the number of nanostructures 108B; the materials of the nanostructure 108T may be different than the nanostructure 108B; and/or the gate electrode material of the top transistor TT may be different than the gate electrode material of the bottom transistor BT, in accordance with some embodiments. Therefore, depending on the types of the resulting integrated circuits, the overall performance of integrated circuits can be improved by optimally adjusting these differences.

Embodiments of a semiconductor structure and the method for forming the same may be provided. The semiconductor structure includes a bottom transistor and a top transistor formed on the bottom transistor. The bottom transistor includes a plurality of first nanostructures and a first gate structure wrapped around the first nanostructures. The top transistor includes a plurality of second nanostructures and a second gate structure wrapped around the second nanostructures. The first width of one of the first nanostructures is greater than a second width of one of the second nanostructures. The semiconductor structure further includes a first middle dielectric layer between the first gate structure and the second gate structure, and the first middle dielectric layer has a third width, and the third width is larger than the second width. The width of the lower channel layers is different than the width of the upper channel layers. Therefore, the performance of the top transistor and that of the bottom transistor may be independently adjusted, thereby improving the overall performance of the resulting integrated circuits.

In some embodiments, a semiconductor structure is provided. The semiconductor structure includes a bottom transistor. The bottom transistor includes a plurality of first nanostructures and a first gate structure wrapped around the first nanostructures. The semiconductor structure also includes a top transistor above the bottom transistor. The top transistor includes a plurality of second nanostructures and a second gate structure wrapped around the second nanostructures. The first width of one of the first nanostructures is greater than the second width of one of the second nanostructures. The semiconductor structure includes a first middle dielectric layer between the first gate structure and the second gate structure, and the first middle dielectric layer has a third width, and the third width is larger than the second width.

In some embodiments, a semiconductor structure is provided. The semiconductor structure includes a plurality of first nanostructures formed along a first direction over a substrate, and a plurality of second nanostructures formed over the first nanostructures along the first direction. The semiconductor structure includes a first gate structure wrapped around the first nanostructures along a second direction. The semiconductor structure includes a second gate structure wrapped around the second nanostructures along the second direction. The gate spacer layer has an inner sidewall surface in direct contact with the second gate structure. The semiconductor structure includes a first middle dielectric layer between the first gate structure and the second gate structure, and a sidewall surface of the first middle dielectric layer extends beyond the inner sidewall surface of the gate spacer layer.

In some embodiments, a method for forming a semiconductor structure is provided. The method includes forming a first stack structure over a substrate, and the first stack structure includes a plurality of first semiconductor materials and a plurality of second semiconductor materials. The method includes forming a sacrificial layer on the first stack structure, and forming a second stack structure on the sacrificial layer. The method includes patterning the second stack structure and the sacrificial layer to form a patterned second stack structure and a patterned sacrificial layer. The method includes forming a spacer layer on a sidewall surface of the patterned second stack structure and a sidewall surface of the patterned sacrificial layer. The method includes patterning the first stack structure by using the patterned second stack structure and the patterned sacrificial layer as a mask to form a patterned first stack structure. The method includes forming a dummy gate structure on the patterned first stack structure, the patterned second stack structure and the patterned sacrificial layer. The method includes removing the patterned sacrificial layer to form a recess, and forming a first middle dielectric layer in the recess. The method includes removing the dummy gate structure to form a trench, and removing the first semiconductor materials of the patterned first stack structure to form first nanostructures. The method includes removing the first semiconductor materials of the patterned second stack structure to form second nanostructures, and forming a first gate structure surrounding the first nanostructures. The method includes forming a second gate structure surrounding the second nanostructures, and the first middle dielectric layer is between the first gate structure and the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a bottom transistor comprising a plurality of first nanostructures and a first gate structure wrapped around the plurality of first nanostructures;
a top transistor above the bottom transistor, comprising a plurality of second nanostructures and a second gate structure wrapped around the plurality of second nanostructures, wherein a first width of one of the first nanostructures is greater than a second width of one of the second nanostructures; and
a first middle dielectric layer between the first gate structure and the second gate structure, wherein the first middle dielectric layer has a third width, and the third width is larger than the second width.

2. The semiconductor structure as claimed in claim 1, wherein the bottom transistor further comprises a first S/D structure, the top transistor further comprises a second S/D structure, and there is a spacer dielectric layer between the first S/D structure and the second S/D structure.

3. The semiconductor structure as claimed in claim 2, wherein a top surface of the spacer dielectric layer is lower than a top surface of the first middle dielectric layer.

4. The semiconductor structure as claimed in claim 1, wherein a first number of the first nanostructures is different from a second number of the second nanostructures.

5. The semiconductor structure as claimed in claim 1, further comprising:
a first inner spacer layer adjacent to the first gate structure, wherein an outer sidewall surface of the first inner spacer layer is aligned with an outer sidewall surface of the first middle dielectric layer.

6. The semiconductor structure as claimed in claim 5, wherein the first inner spacer layer and the first middle dielectric layer are made of different materials.

7. The semiconductor structure as claimed in claim 1, wherein the first gate structure includes a first-type work function layer, and the second gate structure includes a second-type work function layer.

8. The semiconductor structure as claimed in claim 1, further comprising:
a second middle dielectric layer between the first gate structure and the second gate structure, wherein the second dielectric layer is in direct contact with the first middle dielectric layer.

9. A semiconductor structure, comprising:
a plurality of first nanostructures formed along a first direction over a substrate;
a plurality of second nanostructures formed over the first nanostructures along the first direction;
a first gate structure wrapped around the plurality of first nanostructures along a second direction;
a second gate structure wrapped around the plurality of second nanostructures along the second direction;
a gate spacer layer adjacent to the second gate structure, wherein the gate spacer layer has an inner sidewall surface in direct contact with the first gate structure; and
a first middle dielectric layer between the first gate structure and the second gate structure, wherein a sidewall surface of the first middle dielectric layer extends beyond the inner sidewall surface of the gate spacer layer.

10. The semiconductor structure as claimed in claim 9, further comprising:
a first inner spacer layer adjacent to the first gate structure, wherein an outer sidewall surface of the middle dielectric layer extends beyond an interface between the first gate structure and the first inner spacer layer.

11. The semiconductor structure as claimed in claim 9, wherein a first number of the first nanostructures is different from a second number of the second nanostructures.

12. The semiconductor structure as claimed in claim 9, further comprising:
a first S/D structure formed adjacent to the first gate structure;
a second S/D structure formed adjacent to the second gate structure; and
a spacer dielectric layer between the first S/D structure and the second S/D structure, wherein a top surface of the spacer dielectric layer is higher than a top surface of the first middle dielectric layer.

13. The semiconductor structure as claimed in claim 9, wherein one of the first nanostructures has a first width along the second direction, one of the second nanostructures has a second width, and the first width is greater than the second width.

14. The semiconductor structure as claimed in claim 13, wherein the first middle dielectric layer has a third width along the second direction, and the third width is greater than the second width.

15. The semiconductor structure as claimed in claim 9, further comprising:
a second middle dielectric layer between the first gate structure and the second gate structure, wherein the second dielectric layer is in direct contact with the first middle dielectric layer.

16. A method for forming a semiconductor structure, comprising:
forming a first stack structure over a substrate, wherein the first stack structure comprises a plurality of first semiconductor materials and a plurality of second semiconductor materials;
forming a sacrificial layer on the first stack structure;
forming a second stack structure on the sacrificial layer;
patterning the second stack structure and the sacrificial layer to form a patterned second stack structure and a patterned sacrificial layer;
forming a spacer layer on a sidewall surface of the patterned second stack structure and a sidewall surface of the patterned sacrificial layer;
patterning the first stack structure by using the patterned second stack structure and the patterned sacrificial layer as a mask to form a patterned first stack structure;
forming a dummy gate structure on the patterned first stack structure, the patterned second stack structure and the patterned sacrificial layer;
removing the patterned sacrificial layer to form a recess;
forming a first middle dielectric layer in the recess;
removing the dummy gate structure to form a trench;
removing the first semiconductor materials of the patterned first stack structure to form first nanostructures;
removing the first semiconductor materials of the patterned second stack structure to form second nanostructures;
forming a first gate structure surrounding the first nanostructures; and
forming a second gate structure surrounding the second nanostructures, wherein the first middle dielectric layer is between the first gate structure and the second gate structure.

17. The method for forming the semiconductor structure as claimed in claim 16, further comprising:
removing a portion of the first semiconductor materials to form a notch; and
forming an inner spacer layer in the notch, wherein a sidewall surface of the inner spacer layer is aligned with a sidewall surface of the first middle dielectric layer.

18. The method for forming the semiconductor structure as claimed in claim 16, further comprising:
forming a first S/D structure adjacent to the first stack structure;
forming a spacer dielectric layer over the first S/D structure; and
forming a second S/D structure over the spacer dielectric layer, wherein the spacer dielectric layer is between the first S/D structure and the second S/D structure.

19. The method for forming the semiconductor structure as claimed in claim 16, further comprising:
forming a second middle dielectric layer between the first gate structure and the second gate structure, wherein the second dielectric layer is in direct contact with the first middle dielectric layer.

20. The method for forming the semiconductor structure as claimed in claim 16,
wherein a width of the first middle dielectric layer is larger than a width of one of the second nanostructure.
